(19) United States
(12) Patent Application Publication
(10) Pub. No.: US 2011/0220166 A1
(43) Pub. Date: Sep. 15, 2011

(54) METHOD OF SYNTHESIS COBALT ANTIMONIDE NANOSCALE STRUCTURES AND DEVICE

(76) Inventors: Ruxandra Vidu, Citrus Heights, CA (US); Dat Quach, Sacramento, CA (US); Pieter Stroeve, Davis, CA (US)

(21) Appl. No.: 13/039,506

(22) Filed: Mar. 3, 2011

Related U.S. Application Data
(60) Provisional application No. 61/340,000, filed on Mar. 12, 2010.

(51) Int. Cl. H01L 35/20; C09K 3/00; C25D 5/02; C25D 5/18; C25D 1/04

(52) U.S. Cl. 136/240; 252/62.3 T; 205/118; 205/104; 205/108

(57) ABSTRACT

This invention pertains generally to compositions and a method for making films, nanostructures and nanowires in templates and on substrates, including but not limited to metal-semiconductor nanostructures and semiconductor nanostructures on semiconductor substrates, and a device having the same. Particularly described are methods for making cobalt antimonide nanostructures on gold and Co—Sb substrates.

### CROSS-REFERENCE TO RELATED APPLICATIONS

This application claims priority to Provisional Patent Application No. 61/340,000 filed on Mar. 12, 2010 by the present inventors, and all the benefits accruing therefrom under 35 U.S.C. 119, the contents of which in its entirety are herein incorporated by reference.

### BACKGROUND

### Prior Art

The following is the non-patent literature documents of some prior art that presently appears relevant:
Zhang, Y. B., et al., The thermodynamic assessment of the ternary Co—Ni—Sb system. Calphad-Computer Coupling of Phase Diagrams and Thermochemistry, 2009. 33(2): p. 405-414.
Feschotte, P. and D. Lorin, The Binary-Systems Fe—Sb, Co—Sb and Ni—Sb. Journal of the Less-Common Metals, 1989. 155(2): p. 255-269.
Dudkin, L. D. and N. K. Abrikosov, A Physicochemical Investigation of Cobalt Antimonides. Journal of Inorganic Chemistry-Ussr, 1956. 1(9): p. 169-180.
Dudkin, L. D. and N. K. Abrikosov, On the Doping of the Semiconductor Compound Cosb3. Soviet Physics-Solid State, 1959. 1(1): p. 126-133.
Singh, D. J. and W. E. Pickett, Skutterudite Antimonides—Quasi-Linear Bands and Unusual Transport. Physical Review B, 1994. 50(15): p. 11235-11238.
Chitroub, M., F. Besse, and H. Scherrer, Thermoelectric properties of semi-conducting compound CoSb3 doped with Pd and Te. Journal of Alloys and Compounds, 2009. 467(1-2): p. 31-34.
Itoh, T., E. Hattori, and K. Kitagawa, Thermoelectric properties of iron- and lanthanum-doped CoSb3 compounds by pulse discharge sintering. Journal of Propulsion and Power, 2008. 24(2): p. 359-364.
Jung, J. Y., S. C. Ur, and I. H. Kim, Thermoelectric properties of InzCo4Sb12-yTey skutterudites. Materials Chemistry and Physics, 2008. 108(2-3): p. 431-434.
Kim, I. H., K. H. Park, and S. C. Ur, Thermoelectric properties of Sn-doped CoSb3 prepared by encapsulated induction melting. Journal of Alloys and Compounds, 2007. 442(1-2): p. 351-354.
Kim, I. H. and S. C. Ur, Electronic transport properties of Ni-doped CoSb3 prepared by encapsulated induction melting. Metals and Materials International, 2007. 13(1): p. 53-58.
Kim, I. H. and S. C. Ur, Electronic transport properties of Fe-doped CoSb3 prepared by encapsulated induction melting. Materials Letters, 2007. 61(11-12): p. 2446-2450.
Kim, M. J., S. C. Ur, and I. H. Kim, Thermoelectric properties of CoSb3-yTey prepared by hot pressing. Journal of the Korean Institute of Metals and Materials, 2007. 45(3): p. 191-194.
Li, X. Y., et al., Thermoelectric properties of Te-doped CoSb3 by spark plasma sintering. Journal of Applied Physics, 2005. 98(8).
Mallik, R. C., et al., Transport Properties of Sn-Filled and Te-Doped CoSb3 Skutterudites. Metals and Materials International, 2008. 14(5): p. 615-620.
Ur, S. C., J. C. Kwon, and I. H. Kim, Thermoelectric properties of Fe-doped CoSb3 prepared by mechanical alloying and vacuum hot pressing. Journal of Alloys and Compounds, 2007. 442(1-2): p. 358-361.
Wojciechowski, K. T., Effect of tellurium doping on the thermoelectric properties of CoSb3. Materials Research Bulletin, 2002. 37(12): p. PII S0025-5408(01)00758-9.
Zhao, X. Y., et al., Influence of ni doping on the thermoelectric properties of Co4-xNixSb12. Journal of Inorganic Materials, 2006. 21: p. 392-396.
Savchuk, V., et al., Transport and structural properties of binary skutterudite CoSb3 thin films grown by dc magnetron sputtering technique. Journal of Applied Physics, 2002. 92(9): p. 5319-5326.
Behnke, J. F., Prieto, A. L, Stacy A. M., Sands, T., Electrodeposition of CoSb3 nanowires. Proceedings of the 18th International Conference on Thermoelectrics, 1999: p. 451-453.
Chen, L. J., et al., Ordered CoSb3 nanowire arrays synthesized by electrodeposition. Chemistry Letters, 2006. 35(2): p. 170-171.
Chen, L. J., et al., Different preferred orientation CoSb3 nanowire arrays synthesized by electrodeposition. Chinese Journal of Inorganic Chemistry, 2006. 22(5): p. 949-951.
Vidu, R. and S. Hara, In situ EC-AFM observation of Cd electrodeposition on Au(100). Scripta Materialia, 1999. 41(6): p. 617-624.
Vidu, R. and S. Hara, Surface alloyed phase formation at Au(100)/Cd2+ interface during electrodeposition. Electrochemistry, 1999. 67(12): p. 1240-1242.
Vidu, R. and S. Hara, In situ electrochemical atomic force microscopy study on Au(100)/Cd interface in sulfuric acid solution. Journal of Vacuum Science & Technology B, 1999. 17(6): p. 2423-2430.
Hirai, N., et al., Decay of nano-islands on the surface of a Au(111) electrode in contact with sulfuric acid solution. Science and Technology of Advanced Materials, 2004. 5(1-2): p. 115-118.
Kubo, K., N. Hirai, and S. Hara, Decay of nano-islands on Au(100) electrode in sulfuric acid solution with Cl— anions. Applied Surface Science, 2004. 237(1-4): p. 301-305.
Hirai, N., K. Watanabe, and S. Hara, Potential dependence of decay rate of multi-layered on Au(100) single crystals in sulfuric acid solution. Surface Science, 2001. 493(1-3): p. 568-574.
Hirai, N., et al., In situ atomic force microscopy observation on the decay of small islands on Au single crystal in acid solution. Journal of Vacuum Science & Technology B, 2000. 18(1): p. 7-9.
Hirai, N., H. Tanaka, and S. Hara, Enhanced diffusion of surface atoms at metal/electrolyte interface under potential control. Applied Surface Science, 1998. 130: p. 506-511.
R. David, L., CRC Handbook of Chemistry and Physics, 87th ed., CRC Press, Cleveland, Ohio, 2006. 2006.
Garrett, G. a., J. Am. Chem. Soc., 1952. 74: p. 2353.
Erdogan, I. Y. and U. Demir, Synthesis and characterization of Sb2Te3 nanofilms via electrochemical co-deposition method. Journal of Electroanalytical Chemistry, 2009. 633(1): p. 253-258.
Yan, J. W., et al., Electrodeposition of Sb on Au(100) at underpotentials: structural transition involving expansion of the substrate surface. Electrochemistry Communications, 2004. 6(8): p. 843-848.
Wu, Q., et al., An in situ STM study on Sb electrodeposition on Au(111): irreversible adsorption and reduction, underpotential deposition and mutual influences. Journal of Molecular Catalysis a-Chemical, 2003. 199(1-2): p. 49-56.
Holzle, M. H., U. Retter, and D. M. Kolb, J. Electroanal. Chem., 1994. 371: p. 101.
Nandhakumar, I., J. M. Elliott, and G. S. Attard, Electrodeposition of Nanostructured Mesoporous Selenium Films (HI-eSe). Chem. Mater., 2001. 13: p. 3840-3842.
Cheng, H., Hng, H. H., Ma, J. A Study on the Electrodeposition Behavior of Cobalt Antimonides in Citric Based Solutions. Solid State Phenomena, 2008. 136: p. 75-82.
Vicenzo, A., Cavallotti, P. L., Growth Modes of Electrodeposited Cobalt. Electrochimica Acta, 2004. 49: p. 4079-4089.
Cheng H., H. H. H., Ma J., A Study on the Electrodeposition Behavior of Cobalt Antimonides in Citric Based Solutions. Solid State Phenomena, 2008. 136: p. 75-82.
D. V. Quach, R. Vidu, J. R. Groza, P. Stroeve, Electrochemical Deposition of Cobalt Antimonide Thin Films and Nanowires, Journal of Chemical Engineering Research, 49 (2010), 11385-11392.

This invention pertains generally to compositions and a method for making films, nanostructures and nanowires in templates and on substrates, including but not limited to metal-semiconductor nanostructures and semiconductor nanostructures on semiconductor substrates, and a device having the same. Particularly described are methods for making cobalt antimonide nanostructures on gold and Co—Sb substrates.

Thermoelectrics are renewable energy materials that benefit from low dimensionality. Cobalt triantimonide and its derivatives are considered to be the most suitable thermoelectric materials for applications in the range around 600 K. CoSb₃ exhibits excellent electrical transport properties, one of the highest values for hole mobility in a semiconductor due to a high degree of covalent bonding.

Cobalt and antimony form three intermediate compounds (CoSb, CoSb₂ and CoSb₃). CoSb₃ has a very narrow range of solid solubility, forms a eutectic with Sb at about 621° C. and melts incongruently at 873° C. It belongs to a group that has the skutterudite (CoAs₃) structure indicated by MX3 where M represents a metal atom and X a pnictide atom. The compound crystallizes in a body-centered cubic structure with the space group Im3. The unit cells consists of eight corner-shared MX6 octahedra, which produce a large void at the center of (MX6)₈ clusters occupying the body center position in the unit cell. This open site may be further filled with large, “rattling”, rare earth ions (La or Ce) to decreases thermal conductivity. CoSb₃ is a semiconductor with a band gap of 0.5 V as determined experimentally and 0.57 V by calculations. Thermoelectric and electrical transport properties of CoSb₃ are sensitive to dopant concentrations. Important dopants include Fe and Ni (substituted for Co) and Sn and Te (substituted for Sb). Thin films of CoSb₃ have been prepared by different techniques including pulsed laser deposition and dc magnetron sputtering. Thermoelectric materials with filled skutterudite structure for thermoelectric devices. For example, U.S. Pat. No. 6,342,668 Fleurial, et al., Jan. 29, 2002, teaches a method for fabricating a thermoelectric alloy of a filled skutterudite structure from powders using a sintering method.

Although most studies on skutterudites have been focused on the effects of rattler and dopant concentrations on thermoelectric properties, only recent work concentrated on low dimension skutterudites such as thin films and nanowires. Unlike other thermoelectric materials such as Bi₂Te₃, CoSb₃ has a cage structure that offers a unique opportunity for nanowires to combine rattling effect and quantum confinement in obtaining higher figure of merit ZT and more efficient thermoelectric devices.

Since theoretical calculations first predicted a drastic increase of ZT for thermoelectric nanowires, well beyond the stagnant bulk value of 1, significant progress has been made in synthesizing these structures by way of electrodeposition. Most of the electroplating baths were developed first for thin films and then demonstrated for nanowires using nanoporous templates. For example, Behnke et al in “Electrodeposition of CoSb3 nanowires”, Proceedings of the 18th International Conference on Thermoelectrics, 1999: p. 451-453, teaches how to prepare nanowires with Co:Sb≈1:3 using an electrochemical deposition process. However, CoSb₃ nanowires were not obtained directly by electrodeposition but after an additional post-deposition annealing that created the conditions for Co and Sb to react on adjacent layers and form CoSb₃. After annealing, EDS pointed to the presence of cobalt rich phases in small amounts or noncrystalline due to the antimony loss. Therefore, post-deposition annealing is a challenging method to form crystalline CoSb₃ and the right conditions were not achieved.

Chen et al [“Ordered CoSb₃ nanowire arrays synthesized by electrodeposition.” Chemistry Letters, 2006. 35(2): p. 170-171; and “Different preferred orientation CoSb₃ nanowire arrays synthesized by electrodeposition”. Chinese Journal of Inorganic Chemistry, 2006. 22(5): p. 949-951.] teach on the synthesis of crystalline CoSb₃ nanowires using electrochemical deposition. CoSb₃ nanowire arrays were deposited on an alumina template from a solution of SbO⁺, Co²⁺ and tartaric acid.

To improve efficiency of thermoelectric devices, thermoelectric materials with controlled structure and composition need to be developed. I wide selection of thermoelectric materials is now available. However, the temperature ranges at which these materials operate impose some limitation on this selection. Bulk materials are somehow limited in achieving the required levels in thermoelectric properties, including, for example, thermal and electrical conductivity. In order to overcome these limitations, a combination of controlled structures and composition must be achieved. The availability of new nanostructures with novel properties will significantly expand the utilization of these materials for heat waste recovery.

### SUMMARY OF THE INVENTION

Described herein are methods of making nanostructures and nanowires that overcome one or more of the drawbacks of the existing methods. Also described are particular nanostructures and nanowires made using a conductor or semi-conductor substrate made inside and over a non-conductive template. Also described are particular pillar nanostructures made in the absence of a template or over a template.

In one method, nanostructures are produced using a template. The method may also optionally include the step of heating during or after the nanostructures are grown. In one method of making nanostructures, the deposition time is increased to grow pillars. In one method of making cobalt antimonide nanostructures, the nanoscale structures are further doped. In one method of making cobalt antimonide nanostructures, the nanoscale structures are further roughened by a selective dissolution of Sb. In one method, thin films and nanowires were both grown on a gold-coated polycarbonate track-etched (PCTE) membrane. Thin films of cobalt antimonide were grown on the nanostructured Au surface. Nanowires were grown inside the pores of the PCTE membrane. The thin film deposition was performed on a nanostructured gold surface and nanowires were grown electrochemically by template synthesis. Any size of PCTE or anodized aluminum oxide (AAO) membrane can be used.

In one aspect, this invention includes a variety of methods of producing a non-stoichiometric material using electrochemical deposition. Stoichiometric CoSb₃ is produced under certain deposition conditions including electrolyte composition, stirring rate, temperature and deposition (i.e. constant potential or pulsing).

In another method, electrolytes were prepared by dissolving 0.003 M Sb₂O₃ and 0.172 M CoSO₄.7H₂O in aqueous solution containing 0.125 M potassium citrate monobasic and 0.196M citric acid. Sb₂O₃, CoSO4.7H₂O, C6H₇KO₇ (potassium citrate monobasic), and C₆H₈O₇ (citric acid) were used. According to another method, other electrolyte compositions were used, including:

| | Sb₂O₃ | CoSO₄ | C₆H₇KO₇ | C₆H₈O₇ | pH |
|---|---|---|---|---|---|
| SolnP9 | 0.003M | 0.172M | 0.125M | 0.196M | 2.288 |
| SolnP54 | 0.003M | 0.172M | 0.321M | — | 2.874 |
| SolnP69 | 0.003M | 0.010M | 0.125M | 0.196M | 2.604 |
| SolnP72 | 0.003M | 0.064M | 0.125M | 0.196M | 2.399 |

According to yet another method, deposition has been made at temperatures between 25 and 65° C.

According to yet another method, constant and pulsing electrodeposition was used.

### BRIEF DESCRIPTION OF THE DRAWINGS

The invention is described with reference to the several FIG.s of the drawing, in which,

FIG. 1 is a sketch of the nanostructures;

FIG. 2 is cyclic voltammetry of Au in (a) 0.003 M Sb₂O₃+0.125 M potassium citrate+0.196 M citric acid, (b) 0.172 M CoSO₄.7H₂O+0.125 M potassium citrate+0.196 M citric acid, and (c) 0.003 M Sb₂O₃+0.172 M CoSO₄.7H₂O+0.125 M potassium citrate+0.196 M citric acid, v=5 mV/s;

FIG. 3 SEM of Co—Sb film on Au substrate;

FIG. 4 SEM images of the overgrown nanowire surface;

FIG. 5 is a schematic diagram illustrating a process of growing nanostructures according to the present invention;

FIG. 6 is the SEM micrograph of nanowires;

FIG. 7 is the TEM image of Co—Sb nanowires;

FIG. 8 is the EDS spectra of nanowires;

FIG. 9 is a diagram of the ratio of Co to Sb as a function of deposition potential for 400-nm nanorods and their resultant mushrooms/“films” (At −0.8 V, Co:Sb=0 for films in Cheng et al [39], and for both nanowires and mushrooms in this study).

### DETAILED DESCRIPTION OF THE PREFERRED EMBODIMENTS

The invention is described more fully hereinafter with reference to the accompanying drawings, in which exemplary embodiments of the invention are shown. The invention may, however, be embodied in many different forms and should not be construed as limited to the exemplary embodiments set forth herein. Rather these embodiments are provided so that this disclosure will be thorough and complete, and will fully convey the scope of the invention to those skilled in the art. In the drawings, the size and relative sizes of layers and regions may be exaggerated for clarity.

The terminology used herein is for the purposes of describing particular embodiments only and is not intended to be limiting of the invention. Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Also, well-known functions or constructions are not described in detail since they would obscure the invention in unnecessary detail.

An exemplary embodiment of a method for manufacturing Co—Sb nanostructures according to the present invention is characterized in that the shape of a final Co—Sb nanostructure. Cathodic electrodeposition was performed under potentiostatic conditions with a conventional three-electrode setup consisting of a computer-controlled bipotentiostat (Model: AFCBP1). The reference electrode was Ag/AgCl electrode (3 M NaCl). All potentials are given here relative to the Ag/AgCl (0.194 V vs Standard Hydrogen Electrode). The counter electrode was an Au wire. Electrolyte was purged with N₂ for at least 15 minutes before each experiment.

Electrochemical characterization of the CoSb₃ nanowires including cyclic voltammetry (CV) and deposition were performed using a bi-potentiostat (Model AFCBP1, Pine Instrument Co.). Structural characterization was performed using XL30-SFEG, a high-resolution scanning electron microscope (SEM) with energy dispersive X-ray spectroscopy (EDS) capability.

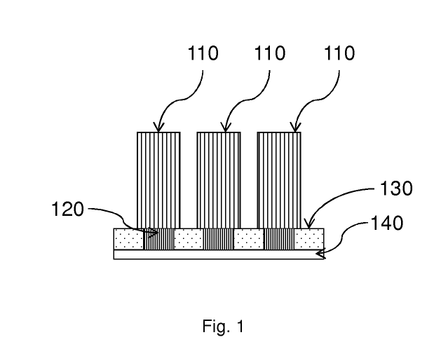

Co—Sb thin film deposition was performed on the nanostructured gold surface and CoSb₃ nanowires were grown electrochemically by template synthesis. The Au coating was characterized by EDS and XRD. Results have shown that the gold film is polycrystalline and has (111) preferred orientation. FIG. 1.c shows the Au coated side of the membrane. Au layer is thin and it doesn't cover the pores. Instead, a conductive ring is formed at the base of the pore (FIG. 1.a), which provides the electrical contact for deposition.

In another aspect, this invention includes a submicron non-stoichiometric Co—Sb material that was produced from a solution containing 0.003 M Sb₂O₃+0.172 M CoSO₄.7H₂O+0.125 M potassium citrate+0.196 M citric acid. A small amount of Sb₂O can be dissolved in water according to the following equation:

Sb₂O₃+H₂O=2HSbO₂ log(HSbO₂)=−3.92 (1)

In acidic solution, antimony can also exist in the form of SbO⁺:

Sb₂O₃+2H⁺=2SbO++H₂O log(SbO⁺)=−3.05−pH (2)

Combining Eqns. (1) & (2), equilibrium between HSbO₂ and SbO⁺ can be established at a given pH:

SbO⁺+H₂O=HSbO₂+H⁺ log [(HSbO₂)/(SbO⁺)]=−0.87+pH (3)

While the concentration of HSbO2 in a saturated aqueous solution is always 1.20×10⁻⁴ M, the concentration of SbO⁺ varies with pH. For pH<0.87, the amount of SbO⁺ in the solution exceeds that of HSbO₂. Since pH of the as-prepared solution is 2.29, the concentration of HSbO₂ in the solution is 26 times greater than that of free SbO⁺. Noteworthy is that the equilibrium amounts of both HSbO₂ and free SbO⁺ in the solution are small compared to the starting 0.003 M Sb₂O₃, and the rest of the initial Sb₂O₃ input stays in complexes between SbO⁺ and citrates. As the deposition proceeds, depletion of HSbO₂ and SbO⁺ is counterbalanced by the dissociation of citrate complexes, so that new equilibrium is established.

Electrodeposition of CoSb₃ involves first the reduction of the absorbed Co²⁺ and HSbO₂ on the electrode to elemental Co and Sb:

Co²⁺+2e⁻=Co(s) E₀=−0.277+0.0295 log(Co²⁺) (4)

HSbO₂+3H⁺+3e⁻=Sb+2H2O, E₀=0.230−0.0591 pH+0.0197 log(HSbO₂) (5)

SbO⁺+2H⁺+3e⁻=Sb+H2O, E₀=0.212−0.0394 pH+0.0197 log(SbO⁺) (6)

Then, the reduced Co and Sb atoms react with each other to form CoSb3. The overall reaction can be expressed as:

Co²⁺+3HSbO₂+9H⁺+11e⁻=CoSb₃+6H₂O (7)

In aqueous solutions, there is a large separation between the reduction potential of Co(II) and Sb(III). Under acidic conditions, the standard reduction potentials of the redox couples: Co^{2+/}Co⁰ and HSbO₂/Sb⁰(or SbO⁺/Sb⁰) are −0.277 and 0.230V (or 0.212 V) vs. SHE, respectively, which is 0.507 V (or 0.489 V) apart. In these conditions, it is difficult to achieve controlled deposition rates for Co and Sb. However, the difference between the reduction potentials of Co²⁺ and HSbO₂/SbO⁺ can be reduced by controlling the composition of the electrolyte. Theoretically the concentrations of HSbO₂, SbO⁺ and Co²⁺ ions in the solution affect the potential at which Sb and Co deposit on the cathode. The concentration of HSbO₂ and SbO⁺ are 1.20×10⁻⁴ M and 4.57×10-6 respectively as determined from Eqns. (1) & (2). The equilibrium concentration of free Co²⁺ is calculated from the MINEQL+ software for the as-prepared solution and equals to 5.56×10⁻² M. Of the initial 0.172 M CoSO₄, about 0.116 M (or 67.4%) of Co²⁺ exists in the form of citrate complexes. The concentration of H⁺ is 5.13×10⁻³ M. The standard potentials ESb/HSbO₂, ESb/SbO⁺, ECo/Co²⁺ and EH/H⁺ are calculated as follow:

E_{Co/Co2+}=−0.277+0.0295 log(Co²⁺)=−0.314 V vs. S.H.E. or −0.508 vs. Ag/AgCl

E_{H/H+}=0.0592 log(H⁺)=−0.136 vs. S.H.E. or −0.330 vs. Ag/AgCl

E_{Sb/HSbO2}=0.230−0.0591 pH+0.0197 log(HSbO₂)=0.017 V vs. S.H.E. or −0.177 V vs. Ag/AgCl

E_{Sb/SbO+}=0.212−0.0394 pH+0.0197 log(SbO⁺)=0.016 V vs. S.H.E. or −0.178 V vs. Ag/AgCl

The gap between E_{Sb/HSbO2} (or E_{Sb/SbO+}) and E_{Co/Co2+} is shortened from 0.507 V (or 0.489 V) under standard conditions to 0.331 V (or 0.330 V) in this solution. Although the gap between the standard potentials are still relatively large and hydrogen evolution is unavoidable, the main purpose of using citrate and citric acid is to form complexes with SbO⁺ and to increase the solubility of Sb₂O₃. Without the formation of complexes, at pH=2.29 the maximum amount of Sb₂O₃ can be dissolved in an aqueous solution is about 6.00×10-5M (i.e., 1.20×10⁻⁴ M HSbO₂). In this example, when citrate/citric acid is used and complexes are formed at the same pH, the total amount of Sb₂O₃ dissolved in the solution is increased to 3.0×10⁻³ M or 50 times greater than the normal condition. Complexes also affect codepositions and formation of compound.

Nanostructured thermoelectric materials combine structural and compositional design. An exemplary embodiment of the principle of the manufacturing method of the present invention can be explained with reference to FIG. 1. FIG. 1, without limiting the scope of this invention, is a sketch illustrating the nanostructures created according to the present invention. Referring to the drawing, thin conductive layer 140 is deposited on the template 130. Nanostructures 120 are formed inside template 130 by electrochemical template synthesis. Nanostructures 120 can be of any height. Nanostructures 120 can also act like seeds for nanostructures 110. Unlike other seed layer method, nanostructures 120 and 110 are of the same system but different composition.

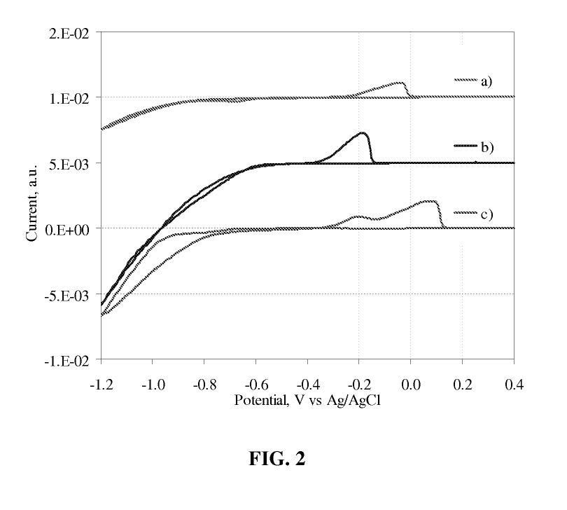

FIG. 2 shows the cyclic voltammetry (CV) of Au in solutions containing only Co²⁺, SbO⁺, or both ions. All voltammetry curves were scanned first in the negative direction from 0.4 V. For Sb deposition (FIG. 2.a), the reduction point is seen at a potential of −0.6 V in a forward scan. The corresponding oxidation potential is around −0.05 V. Sb—Au is among the systems that show underpotential deposition (UPD). The cyclic voltammograme for antimony UPD on the Au (111) in acidic solution contains two redox couples corresponding to the deposition and stripping of Sb atomic layers. The bulk Sb deposition in the acidic solution (pH=1.5) does not occur until −200 mV. A simple electrochemical reducing process, for example, SbO⁺→Sb⁰, is accepted widely and described as SbO⁺+3e⁻+2H⁺→Sb0+H₂O. The process is more complicated than the electrochemical equation since three electrons cannot be obtained in one electrochemical reducing step. It is well known that complex reagents are always needed in the solution in order to increase the solubility of Sb(III) and also its stability. For Co deposition (FIG. 2.b), the reduction point is seen around −0.3 V in a forward scan. The corresponding oxidation potential is around −0.2 V. For the Co—Sb system, deposition from a solution containing both Co and Sb ions (FIG. 2.c), starts around −0.4 V. The oxidation peak at −0.2 V is consistent with the cathodic waves resulting from the reduction of Co(II) to Co metal. In FIG. 2, the negative potential limit was set to −1.2 V, negative to the potential where H₂ evolution commences on Au surface. It can be seen that on the first potential scan towards more negative potential there are two reduction waves. The waves overlap to some extent. The back scans toward more positive potentials shows also two overlapping reduction waves and substantial cathodic current is observed at all potentials negative to −0.3 V. When a second scan is recorded immediately after the first scan, without any additional treatment, the current is similar to the first scan, but not identical. Surface modification due to the interaction between Sb and Au may be responsible for the differences in consecutive CVs. The cross-over in the voltammograms of FIG. 2 are most commonly associated with systems that involve the nucleation and growth of a new phase on the electrode surface. Hence, the voltammograms on the reverse and second scans appear to be for the reduction of Co and Co—Sb at a newly formed Sb—Au surface. All the voltammograms imply that the nucleation of Co—Sb phase is a complicated process requiring a large overpotential. The most negative cathodic waves show an increase in height and may result from a larger contribution from hydrogen adsorption on the growing Co—Sb surface.

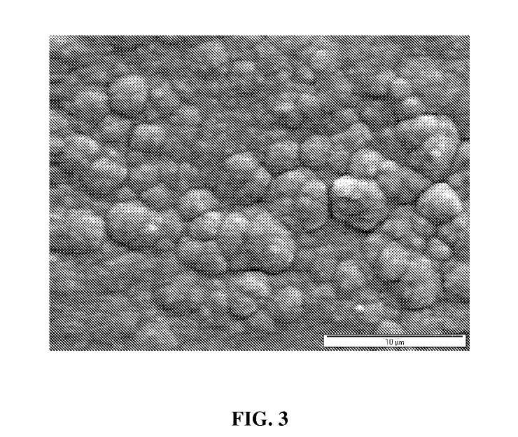

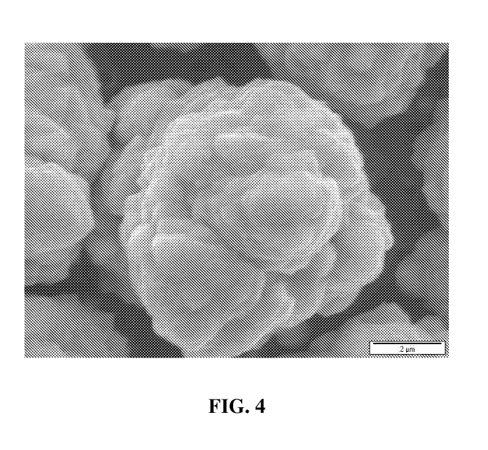

FIG. 3 shows a typical image of the Co—Sb film on Au. The film is relatively uniform and deposits on the entire conductive surface. FIG. 4 shows a typical SEM image of the Co—Sb film on Co—Sb nanowires consisting of mushroom cups of over-grown nanowires, i.e. nanowires that grew over the template surface. The uniqueness of this surface is given by the pillar-like structure of the mushroom cups. This morphology is completely different from the Co—Sb film grown on Au. Nanowires were grown in the same solution as the deposition of Co—Sb film, i.e. 0.003 M Sb₂O₃+0.172 M CoSO₄.7H₂O+0.125 M potassium citrate+0.196 M citric acid. Unlike thin films, the formation of Co—Sb nanowires is a complex process induced by the template spatial limitations. First, Co²⁺ and SbO⁺ ions are driven by both electric field and concentration gradient into the nanopores of the template while the diffusion of HSbO₂ is only influenced by its concentration gradient. The charge applied to the electrode surface provides the electrons to produce elemental Co and Sb (reactions 4 and 5). Then, the reaction between Co and Sb results in the formation of CoSb₃ and the growth of nanowires.

This invention teaches a method for engineering unusual nanostructures with multi-layer stoichiometric/nonstoichiometric compositions. In general, in the process of nanowires electrodeposition, the deposit fills the pores of a template from the bottom. For extended deposition time, the deposit grows isotropically over the template, resulting in semispherical mushroom caps that quickly form a film over the template. This type of isotropic growth has been generally observed and is expected to occur in the template synthesis process. However, the SEM micrographs in FIG. 4 clearly show free-standing pillars. This behavior is new and completely different from other systems that use electrochemical template synthesis. A preferential growth in the vertical direction occurs, resulting in free-standing pillars. The pillars start to grow from one or more pores, where the conducting surface is exposed. After the pores were filled, the deposit grew anisotropically in the vertical direction and maintained the shape but not the size of the pores or the composition of nanostructures that grew inside the pores. Mushroom pillars are bigger than nanowires, suggesting that the lateral growth is significant in the beginning of the nanowire overgrow. However, the individual surface pillars show preferential growth in the vertical direction, independently of each other. The Co—Sb pillars stand straight up, suggesting they are rigid enough to withstand the hydrodynamic force during the plating. The resulting surface of the overgrown nanowires is not fully dense (FIG. 4) and cannot be directly compared to the film (FIG. 3). The SEM micrographs suggest that on the PCTE template, vertical growth is much easier than lateral growth. At this growth rate it may take a significant amount of time, if ever, to cover completely the template surface.

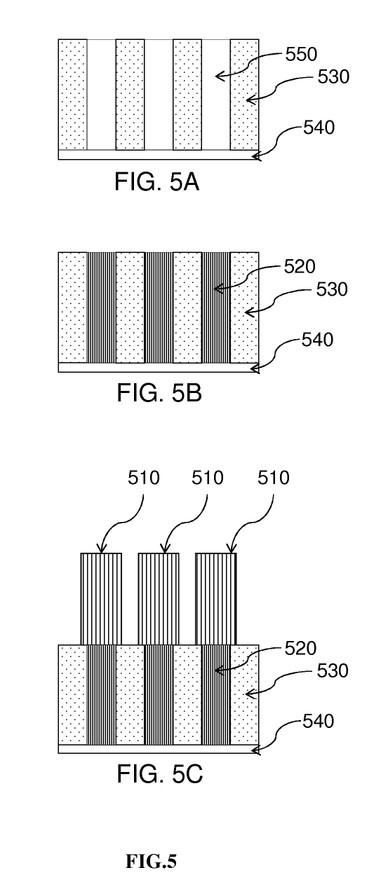

An exemplary embodiment of the principle of the manufacturing method of the present invention can be explained with reference to FIGS. 5A, 5B and 5C. FIG. 5, without limiting the scope of this invention, are sketches illustrating the nanostructures created according to the present invention. Referring to the drawing, thin conductive layer 540 is deposited on the template 530. Nanostructures 520 are formed inside the pores 550 of template 530 by electrochemical template synthesis. Nanostructures 520 can be of any height. Nanostructures 520 can also act like seeds for nanostructures 510. Unlike other seed layer method, nanostructures 520 and 510 are of the same system but different composition.

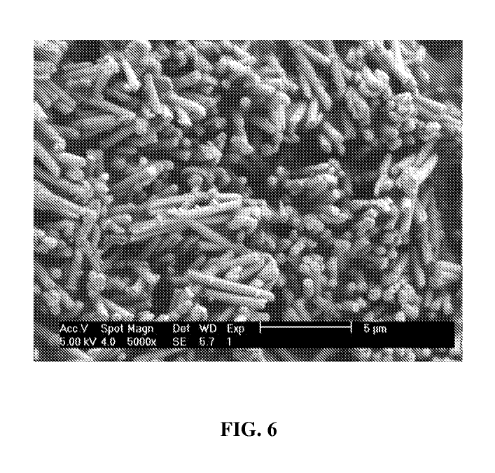

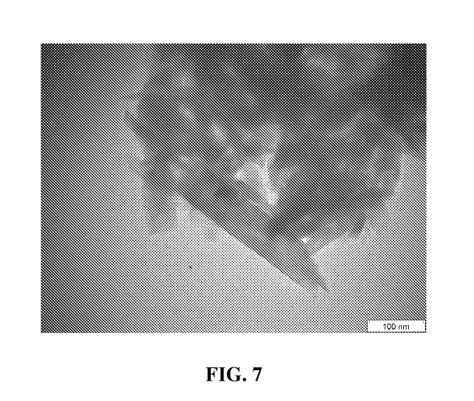

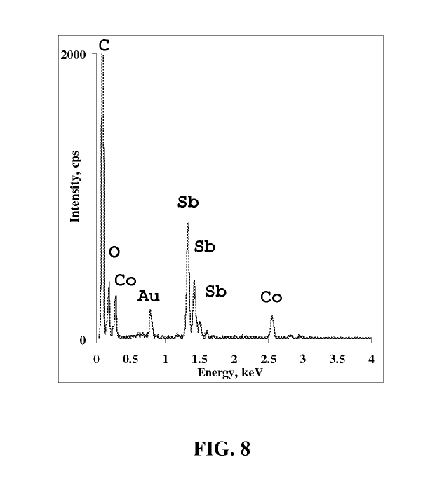

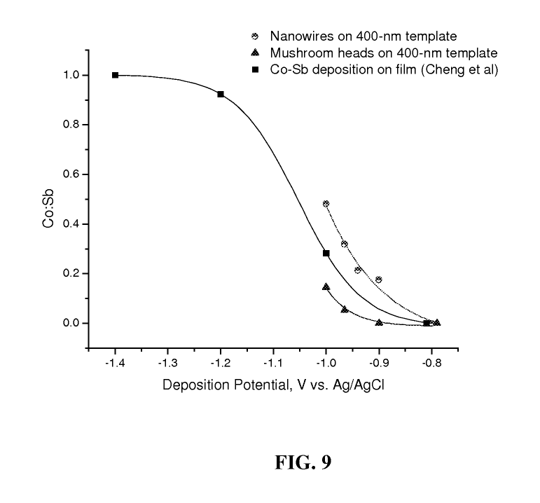

FIG. 6 shows SEM image of nanostructures 520 in the form of nanowire array after the template was dissolved in dichloromethane. FIG. 7 shows the TEM image of nanostructures 520 in the form of nanowires/nanorods after the template was dissolved in dichloromethane. EDS results (FIG. 8) show that the elemental composition of nanowires. EDS results show that the elemental composition of nanowires, nanowire heads and cauliflower-like films obtained in one sample are different. FIG. 9 shows the ratio of Co to Sb as a function of deposition potential for 400-nm nanorods and their resultant mushrooms/“films”. Deposits inside the template have a higher content of Co. For example, while EDS of nanowires grown inside a 400-nm PCTE template gives an average ratio of Co:Sb of 0.175, the composition of the overgrown nanowire caps obtained under the same deposition condition shows virtually no Co. Results are compared with data obtained by Cheng et. al [Cheng H. et al. “A Study on the Electrodeposition Behavior of Cobalt Antimonides in Citric Based Solutions”, Solid State Phenomena, 2008. 136: p. 75-82]. Cheng's data were obtained for cobalt antimonide films deposited on stainless steel. Compared to nanowires, the deposition of a film of a composition similar to nanowire takes place at more negative potential. Mushroom caps formed by overgrown nanowire show a lower Co:Sb ratio when compared to film or nanowires. It is possible that Sb deposition inside nanopores is a diffusion-controlled process, and the small pore size of the template hinders its deposition.

Although the exemplary embodiments of the present invention have been described, it will be understood by those skilled in the art that the present invention should not be limited to the described exemplary embodiments, but various changes and modifications can be made within the spirit and scope of the present invention as defined by the appended claims.

What is claimed is:

1. A method of synthesizing films and nanoparticles, comprising: forming a solution of a Group VIII reagent and Group V reagent, adding a reducing agent to the solution, and maintaining the resultant solution at an elevated temperature in a range of about 20 to about 65° C. under potential control for a time duration so as to generate nanostructures containing said Group VIII and Group V elements.

2. The method of claim 1, further comprising selecting said complex reagents to be any of citrate/citric acid.

3. The method of claim 1, further comprising selecting said Group VIII element to be Co, Ni, Fe.

4. The method of claim 1, further comprising selecting said Group V element to be any of Sb or As.

5. The method of claim 1, further comprising depositing a product generated subsequent to the step of electrochemically maintaining the working electrode at a constant potential.

6. The method of claim 1, further comprising depositing a product generated subsequent to the step of electrochemically maintaining the working electrode at pulsing deposition conditions.

7. A device, comprising: a conductive substrate; a template consisting of a plurality of transversal nanopores; and a plurality of Co—Sb nanostructures grown on the conductive substrate; wherein dimensions of the Co—Sb nanostructures are substantially uniform.

8. The device of claim 7, wherein the Co—Sb nanostructures have one diameter size dictated by template.

9. The device of claim 7, wherein the Co—Sb nanostructures have two diameter sizes of various heights.

10. The device of claim 7, wherein the Co—Sb nanostructures have two diameter sizes of various heights and compositions.

11. The device of claim 7, further comprising selecting said Co—Sb such that said resultant nanostructures are n- and p-type semiconductor properties of two different heights.

12. The device of claim 7, further comprising selecting said Co—Sb such that said resultant nanostructures are of stoichiometric/nonstoichiometric composition of two different heights.

13. A thermoelectric composition comprising: a nanostructure comprising a first Co—Sb skutterudite, a nanostructure comprising a second Co—Sb skutterudite, said second skutterudite being coherent with the first skutterudite, said nanostructures of the second Co—Sb skutterudite has a different composition than the first Co—Sb skutterudite, so that the nanostructures decrease the thermal conductivity of the composition by scattering phonons in the composition while substantially maintaining or increasing electrical conductivity and Seebeck coefficient of the composition.

14. The thermoelectric composition of claim 13, wherein at least a portion of the second Co—Sb skutterudite is coherent with one or more of the first Co—Sb skutterudite.

15. The thermoelectric composition of claim 13, wherein at least a portion of the first Co—Sb skutterudite is stoichiometric and a portion of the second Co—Sb skutterudite is nonstoichiometric.

16. The thermoelectric composition of claim 13, wherein at least a portion of the first Co—Sb skutterudite is nonstoichiometric and a portion of the second Co—Sb skutterudite is stoichiometric.

17. The thermoelectric composition of claim 13, wherein the first and second Co—Sb skutterudite comprises doped skutterudite.

18. The thermoelectric composition of claim 13, wherein the second Co—Sb skutterudite comprises different chemistry.

19. The thermoelectric composition of claim 13, wherein the second Co—Sb skutterudite has a Co:Sb ratio less than the first skutterudite.
